(19) United States
(12) Patent Application Publication
(10) Pub. No.: US 2024/0297633 A1
(43) Pub. Date: Sep. 5, 2024

(54) INTERDIGITAL TRANSDUCER ARRANGEMENTS WITH SPURIOUS WAVE SUPPRESSION FOR SURFACE ACOUSTIC WAVE DEVICES

(71) Applicant: Skyworks Solutions, Inc., Irvine, CA (US)

(72) Inventors: Rei Goto, Osaka-Shi (JP); Hironori Fukuhara, Ibaraki-Shi (JP)

(21) Appl. No.: 18/592,928

(22) Filed: Mar. 1, 2024

Related U.S. Application Data
(60) Provisional application No. 63/449,490, filed on Mar. 2, 2023.

(51) Int. Cl. H03H 9/02; H03H 9/64

(52) U.S. Cl. CPC H03H 9/02992; H03H 9/6483

(57) ABSTRACT

An interdigital transducer assembly for a surface acoustic wave device has a pair of busbars with a plurality of interdigitated electrode fingers therebetween. Each electrode finger begins its length at one of the busbars and has an electrode tip that extends towards but does not reach the other busbar. A pair of mass loading strips are each disposed above a respective set of the electrode tips and having a plurality of mass loading stubs arranged along the length of the mass loading strip, with the stubs each aligned with a corresponding electrode tip.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to interdigital transducers (IDTs) for surface acoustic wave (SAW) devices which can suppress undesired wave propagation, such as wave propagation extending from the tips of electrode fingers of an IDT towards a busbar of an IDT.

### Description of the Related Technology

Simple SAW devices consist of a set of interleaved electrodes disposed at a first end of a piezoelectric substrate and a second set of interleaved electrodes disposed at a second end of the piezoelectric substrate. Surface acoustic waves are propagated by the transmitting electrodes, across the surface of the piezoelectric material, and then converted back from physical waves to electrical signals via the piezoelectric effect.

SAW devices are typically tuned to receive, or band-pass a particular frequency. This tuning is performed by selecting materials which make up the interdigital transducer (IDT) transmitter or receiver of the SAW device, or the piezoelectric substrate along which the waves pass.

However, when the IDT transmitter generates acoustic waves in the substrate, the waves can propagate not only towards the IDT receiver, but also outwards from the IDT electrodes towards the busbar. This causes a degradation in the filter quality, as well as requiring more power to compensate for losses.

### SUMMARY

In some aspects, the techniques described herein relate to an interdigital transducer assembly for a surface acoustic wave device, the interdigital transducer including: a pair of busbars parallel to and spaced from one another and a plurality of interdigitated electrode fingers extending between the pair of busbars, each electrode finger beginning its length at one busbar of the pair of busbars and having an electrode tip that extends towards but does not reach the other busbar, the pair of busbars and the plurality of electrode fingers above a piezoelectric substrate; and a pair of mass loading strips each parallel and proximate to a corresponding busbar of the pair of busbars, each disposed above a respective set of the electrode tips, and each having a plurality of mass loading stubs arranged along the length of the mass loading strip, each mass loading stub aligned with a corresponding electrode tip of the respective set of electrode tips and extending from the respective mass loading strip, past an end of the corresponding electrode tip, towards the corresponding busbar.

In some aspects, the techniques described herein relate to an interdigital transducer assembly wherein the plurality of interdigitated electrodes form an active region where the plurality of interdigitated electrode fingers interleave.

In some aspects, the techniques described herein relate to an interdigital transducer assembly wherein a gap region is formed between each busbar of the pair of busbars and a set of the electrode tips that extend towards that busbar.

In some aspects, the techniques described herein relate to an interdigital transducer assembly wherein the mass loading strips are configured to reduce an amplitude of waves generated in the gap region.

In some aspects, the techniques described herein relate to an interdigital transducer assembly wherein the mass loading stubs extend into the gap region.

In some aspects, the techniques described herein relate to an interdigital transducer assembly wherein the mass loading strips and the mass loading stubs are formed from at least one of molybdenum, tungsten, platinum, titanium, copper, and tantalum pentoxide.

In some aspects, the techniques described herein relate to an interdigital transducer assembly wherein the mass loading strips have a width of between 0.5 and 1 wavelength of a wave configured to be propagated by the interdigital transducer.

In some aspects, the techniques described herein relate to an interdigital transducer assembly wherein the mass loading strips have a width of 0.6 of a wavelength of a wave configured to be propagated by the interdigital transducer.

In some aspects, the techniques described herein relate to an interdigital transducer assembly wherein the mass loading stubs have a length of between 0.01 and 1.1 wavelengths of a wave configured to be propagated by the interdigital transducer.

In some aspects, the techniques described herein relate to an interdigital transducer assembly wherein the mass loading stubs have a length of between 0.05 and 0.5 wavelengths of a wave configured to be propagated by the interdigital transducer.

In some aspects, the techniques described herein relate to an interdigital transducer assembly wherein the mass loading stubs have a length of 0.25 of a wave configured to be propagated by the interdigital transducer.

In some aspects, the techniques described herein relate to an interdigital transducer assembly wherein the substrate is formed from Lithium Niobate.

In some aspects, the techniques described herein relate to an interdigital transducer assembly wherein the interdigital transducer is configured to generate acoustic waves on the piezoelectric substrate.

In some aspects, the techniques described herein relate to an interdigital transducer assembly wherein the pair of busbars and the electrode fingers include aluminum.

In some aspects, the techniques described herein relate to an interdigital transducer assembly wherein the pair of busbars the electrode fingers are formed from a first layer and a second layer.

In some aspects, the techniques described herein relate to an interdigital transducer assembly wherein the first layer is made from aluminum.

In some aspects, the techniques described herein relate to an interdigital transducer assembly wherein the second layer is made from any of one of tungsten, copper, gold, silver, platinum, ruthenium, molybdenum.

In some aspects, the techniques described herein relate to an interdigital transducer assembly wherein the mass loading stubs form a sinusoidal profile along the length of the mass loading strip, with each mass loading stub forming a peak of the sinusoidal profile.

In some aspects, the techniques described herein relate to an interdigital transducer assembly further including a silicon base layer disposed beneath the piezoelectric substrate.

In some aspects, the techniques described herein relate to an interdigital transducer assembly further including a temperature coefficient of frequency layer disposed above the piezoelectric substrate.

In some aspects, the techniques described herein relate to a surface acoustic wave device including: a first interdigital transducer including a pair of spaced apart parallel busbars and a plurality of interdigitated electrode fingers extending therebetween, each electrode finger beginning its length at one busbar of the pair and having an electrode tip that extends towards but does not reach the other busbar, the pair of busbars and the plurality of electrode fingers above a piezoelectric substrate, the first interdigital transducer further including a pair of mass loading strips each parallel and proximate to a corresponding busbar of the pair of busbars, each disposed above a respective set of the electrode tips, and each having a plurality of mass loading stubs arranged along the length of the mass loading strip, each mass loading stub aligned with a corresponding electrode tip of the respective set of electrode tips and extending from the respective mass loading strip, past an end of the corresponding electrode tip, towards the corresponding busbar; a second interdigital transducer; and a piezoelectric substrate extending beneath and between the first interdigital transducer and the second interdigital transducer.

In some aspects, the techniques described herein relate to a surface acoustic wave device wherein the first interdigital transducer is configured to generate an acoustic wave in the piezoelectric substrate, and where in the second interdigital transducer is configured to receive the acoustic wave from the piezoelectric substrate.

In some aspects, the techniques described herein relate to a surface acoustic wave device wherein the second interdigital transducer has the same structure as the first interdigital transducer.

In some aspects, the techniques described herein relate to a surface acoustic wave filter including the surface acoustic wave device.

According to one embodiment there is provided an interdigital transducer for a surface acoustic wave device. The interdigital transducer comprises an interdigital transducer part which comprises a plurality of parallel electrode fingers, each having alternate ends respectively connected to first and second busbars on opposite ends of the fingers, and alternate ends respectively unconnected to the first and second busbars. The electrode fingers have electrode tips on the unconnected ends, the electrode fingers and busbars being disposed on a piezoelectric substrate. The interdigital transducer also comprises a mass loading part, which comprises a pair of mass loading strips disposed vertically above the electrode tips, parallel to the busbars and a plurality of mass loading stubs extending from each mass loading strip, each mass loading stub vertically aligned with and extending past a respective electrode tip towards the adjacent busbar.

Mass loading stubs are located above and extending beyond the electrode fingers of the IDT. In this position the waves which would be generated at the tip of the electrode fingers, and which could then propagate outwards instead of along the IDT, are reduced or suppressed, thus increasing the quality of the filter and reducing the power needed to generate acoustic waves in the substrate.

In a further example the interdigital transducer part forms an active region where the plurality of electrode fingers interleave and in a further example the interdigital transducer part forms a gap region between each electrode tip and the adjacent busbar. The gap region is defined as an area where it is not desirable to propagate surface acoustic waves, whereas it is desired to produce waves in the active region. Waves generated in any direction in the gap region are unlikely to be usefully received at a reception IDT. The gap region and the active region are defined such that they extend upwards from the IDT. That is to say, that the gap region is a region including and extending substantially above the IDT layer.

In a further example the mass loading part is configured to reduce the amplitude of waves generated in the gap region. Reducing the amplitude of the waves in the gap region amounts to a useful suppression of those waves.

In a further example the mass loading stubs extend into the gap region. As discussed above, suppression of waves in the gap region allows for an increase in quality of the filter. By extending the mass loading stubs into the gap region this is achieved. Based on the definitions given above, the gap region is not necessarily just a region on the piezoelectric substrate. That is, the stubs do not touch the substrate by extending into the gap region. This will become apparent with reference to the drawings included herein.

In one example the mass loading strips and the mass loading stubs are formed from at least one of molybdenum, tungsten, platinum, titanium, copper, and tantalum pentoxide (Ta2O5).

In a further example the mass loading strips have a width of between 0.5 and 1 wavelength of a wave configured to be propagated by the interdigital transducer, and in a further example mass loading strips have a width of 0.6 of a wavelength of a wave configured to be propagated by the interdigital transducer,

In a further example the mass loading stubs have a length of between 0.01 and 1.1 wavelengths of a wave configured to be propagated by the interdigital transducer, and in a further example the mass loading stubs have a length of between 0.05 and 0.5 wavelengths of a wave configured to be propagated by the IDT, and further still, in an example the mass loading stubs have a length of 0.25 of a wave configured to be propagated by the interdigital transducer. As will be discussed in detail below, a general improvement to interdigital transducer not having mass loading stubs is achieved over the ranges above, however a much larger improvement is achieved at 0.25 wavelengths (L).

In one example the piezoelectric substrate is formed from Lithium Niobate. In a further example the piezoelectric substrate is 20YX—LiNbO3. The Lithium Niobate structure allows for waves generated on the surface of the piezoelectric material to propagate across to an adjacent IDT. The rotated 20 degrees Y cut X propagation LiNbO3 is advantageous for the piezoelectric effect required for the SAW device to operate. In another example the piezoelectric substrate is Lithium Niobate with a cut angle ranged between 115YX and 132YX. Preferably the piezoelectric substrate is 128YX—LiNbO3. Again these cut angles are advantageous for the piezoelectric effect required for the SAW device to operate.

In a further example the interdigital transducer part is configured to generate acoustic waves on the substrate. Generating acoustic waves from an electrical signal at the IDT and in the substrate allows the signal to be received by a receiving IDT as acoustic waves and returned to a filtered electrical signal.

In one example the IDT is formed from aluminum. As the IDT physically creates waves across the surface of the SAW device, the physical properties of the wave generating device, which is an IDT, affects the wavelength of the waves propagated across the SAW device. Other metals can be used for the IDT, depending on the wavelength or frequency of signals required. Heavier IDTs can be used, which can shorten the wavelengths of the SAW device and therefore allow the SAW device to be minimized.

In a further example the interdigital transducer comprises a first layer and a second layer. In a further example the first layer is formed from aluminum and in a further example the second layer is formed from any of one of tungsten, copper, gold, silver, platinum, ruthenium, molybdenum. By providing a two layer IDT it is possible to tune the IDT to achieve both zero TCF and also the wavelength required by the SAW device. By providing a heavier top layer the wavelength of the induced wave is reduced due to the physical inertia required to move the IDTs to generate waves. As there is a relationship between the wavelength of the SAW and the distance between IDT fingers, the device can be made smaller when the wavelength of the induced SAW is smaller.

In a further example the mass loading stubs form a sinusoidal profile on the mass loading strip, with peaks vertically aligned with and extending past a respective electrode tip towards the adjacent busbar.

A sinusoidal mass loading part is beneficial as it provides a comparable improvement to the mass loading part comprising rectangular stubs described herein.

In a further example the interdigital transducer further comprises a silicon base layer disposed beneath the piezoelectric substrate.

In a further example the interdigital transducer further comprises a temperature coefficient of frequency layer disposed above the piezoelectric substrate.

The resonant frequency of a surface acoustic wave (SAW) filter is set to tune the filter to the particular frequency desired to be processed by the filter. It is therefore beneficial to ensure stability of the resonant frequency of the SAW filter. By providing a temperature compensation layer at the between a substrate and an interdigital transducer (IDT) of the filter, the drift caused by changes in temperature can be reduced and removed. In one example the first temperature compensation layer is formed from Silicon Dioxide, SiO2. Silicon dioxide when disposed on the piezoelectric substrate and beneath the IDT can be advantageously tuned by modifying the thickness of the compensation layer, so that 0 TCF (temperature coefficient of frequency) is achieved at both the resonant and anti-resonant frequencies of the SAW device.

According to another embodiment there is provided a surface acoustic wave filter comprising a first and second interdigital transducer according any of the embodiments or examples described above, wherein the piezoelectric substrate extends between the first interdigital transducer and the second interdigital transducer, and in a further example the first interdigital transducer is configured to generate an acoustic wave in the piezoelectric substrate, and where in the second interdigital transducer is configured to receive the acoustic wave from the piezoelectric substrate.

According to another embodiment there is provided a surface acoustic wave filter comprising a first interdigital transducer according to any of the embodiments or examples described above, along with a second interdigital transducer, wherein the piezoelectric substrate extends between the first interdigital transducer and the second interdigital transducer, and the first interdigital transducer is configured to generate an acoustic wave in the piezoelectric substrate, and wherein the second interdigital transducer is configured to receive the acoustic wave from the piezoelectric substrate.

As will be described in greater detail, a SAW device can be constructed using one or two of the IDTs described above. In particular, both the transmission and reception IDT can have the mass loading stubs according to the present invention. In addition, just the transmission IDT can be one according to the invention, and a reception IDT can be one without mass loading stubs, as waves are not propagated from the reception IDT.

According to another embodiment there is provided a method of reducing transverse waves in a surface acoustic wave device. The method comprises disposing a pair of mass loading strips each comprising a plurality of mass loading stubs disposed vertically above a gap region of an interdigital transducer where electrodes of the interdigital transducer are unconnected from a busbar of the interdigital transducer.

Mass loading stubs are located above and extending beyond the electrode fingers of the IDT. In this position the transverse waves which would be generated at the tip of the electrode fingers, and which could then propagate outwards instead of along the IDT, are reduced or suppressed, thus increasing the quality of the filter and reducing the power needed to generate acoustic waves in the substrate.

In one example the mass loading strips and the mass loading stubs are formed from at least one of molybdenum, tungsten, platinum, titanium, copper, and tantalum pentoxide.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1A shows an IDT including a mass loading strip.

FIG. 1B shows a second IDT including a wide mass loading strip.

FIG. 2 shows an IDT including an improved mass loading part according to the present invention.

FIG. 3 shows a plot illustrating the improvement of the mass loading part according to the present invention.

FIG. 4 shows a cross section view through an IDT according to the present invention.

FIG. 5 shows a plot illustrating the modifications to the mass loading part according to the present invention.

FIG. 6 shows a representation of the effectiveness of modifications to the mass loading part according to the present invention.

FIG. 7A shows a modification to the to the mass loading part according to the present invention.

FIG. 7B shows the effectiveness of the modification according to FIG. 7A.

FIG. 8A shows an example modification of the mass loading part according to the present invention.

FIG. 8B shows an example modification of the mass loading part according to the present invention.

FIG. 8C shows an example modification of the mass loading part according to the present invention.

FIG. 9A shows an IDT with improved temperature coefficient of frequency properties.

FIG. 9B shows an IDT with improved resistance.

FIG. 10 shows an example of a ladder filter in which multiple SAW devices incorporating improved mass loading parts according to the present invention may be combined;

FIG. 11 is a block diagram of one example of a filter module that can include one or more low velocity SAW devices incorporating improved mass loading parts according to aspects of the present disclosure;

FIG. 12 is a block diagram of one example of a front-end module that can include one or more filter modules including low velocity SAW devices incorporating improved mass loading parts according to aspects of the present disclosure;

FIG. 13 is a block diagram of one example of a wireless device including the front-end module of FIG. 12.

### DETAILED DESCRIPTION

Aspects and embodiments described herein are directed to multi chip modules, particularly front end modules. In the following description, the term multi chip module (MCM) and front end module may be used interchangeably.

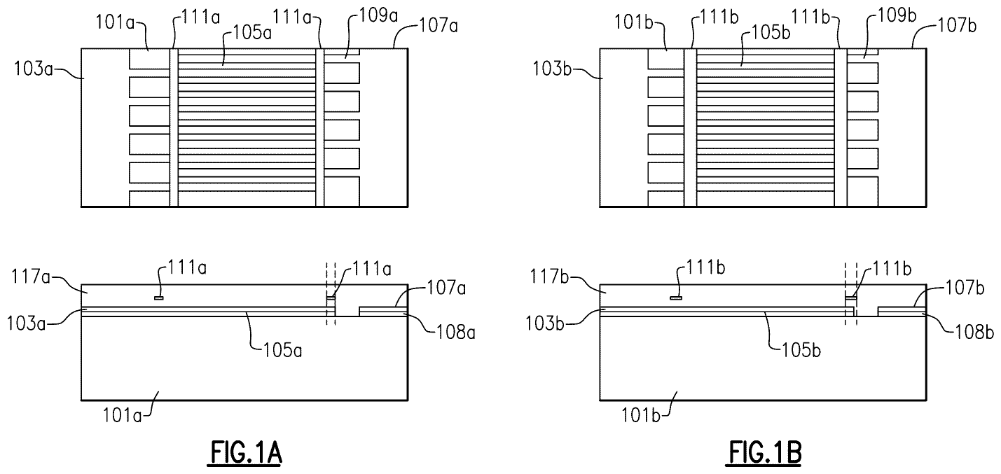

FIG. 1A shows a plan view and a cross-section view of an IDT. Referring first primarily to the plan view, the IDT comprises an IDT part formed from pair of busbars 103a and 107a, each busbar having extending therefrom a set of electrode fingers, 105a for the first busbar 103a and 109a for the second busbar 107a. The busbars and fingers are disposed on a piezoelectric substrate 101a. A surface acoustic wave device can be formed by arranging two IDTs on the piezoelectric substrate 101a, separated from each other.

The SAW device works as a filter by generating a signal at a first IDT and receiving that signal at a second IDT. The first IDT creates a physical wave in the piezoelectric substrate which is turned back into an electrical signal at the second IDT. The medium used to propagate the waves as well as the spacing between IDT fingers sets the passing frequency of the SAW device. Because of the physical properties of the device, and the physical manifestation of the RF waves, temperature can affect the resonant frequency of the device. As the temperature of the device increases, the physical properties of the piezoelectric substrate change, and thus the resonant frequency of the SAW device changes.

The IDT also comprises a pair of mass loading strips 111a disposed above the IDT. As can be seen from the drawings, the electrode fingers 105a and 109a have a connected end and an unconnected end. That is the first electrode fingers 105a comprise every other electrode finger on the IDT and these are all connected to the first busbar 103a. Every other electrode finger then comprises the second electrode fingers 109a and are connected to the second busbar. This means that each of the first electrodes 105a has a connected end where it is connected to the first busbar 103a and each of the second electrodes 109a has a connected end where it is connected to the second busbar 107a.

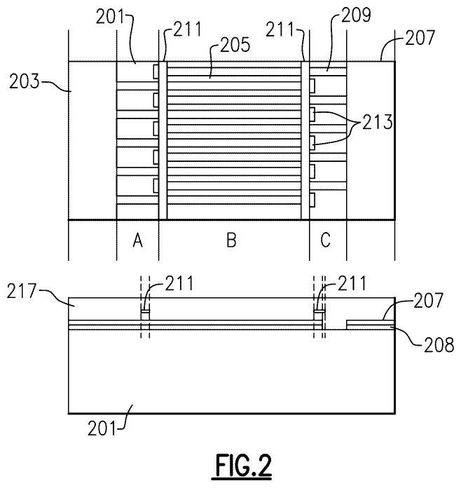

In turn, each of the first electrodes 105a has an opposite unconnected end where it is separated from the second busbar 107a, and each of the second electrodes 109a has an unconnected end where it is separated from the first busbar 103a. This separates the IDT into a five sections (shown in FIG. 2) working from left to right on FIG. 1a, comprising: i. the first busbar 103a, ii. a first gap region A, iii. an active region B, iv. a second gap region C, and v. the second busbar 107a. The electrode fingers only overlap in the active region B, and it is desired to generate waves only in this region. The mass loading strips 111a are located so as to be directly above an end portion of the electrode fingers. That is, the mass loading strips 111a are in the active region B where it borders each gap region A and C.

In the gap regions, defined as areas essentially where only the first or second electrodes fingers are disposed, but not both, waves are also generated. The waves generated by the IDT extend perpendicular to the electrode finger perimeter. This means that in the active region B the waves extend forwards and backwards from a first electrode finger directly to a second electrode finger, however in the gap region A or C the waves extend outwards towards the busbars.

The mass loading strips 111a help to limit the waves propagated outside of the active region.

FIG. 1A also shows a cross section view where the second busbar 107a is shown on the right and the first busbar 103a and a first electrode finger 105a is shown on the left, atop the piezoelectric substrate 101a. The mass loading strips 111a are shown above and slightly separated from the IDT. The right mass loading strip 111a is entirely above the electrode finger 105a and does not extend into the gap region C.

Beneath the IDT is a layer 108a which denotes a two layer IDT. To tune the IDT to a useable frequency whilst keeping the size of the IDT small, a heavy material may be placed beneath the IDT busbars and electrodes to slow down waves generated by the IDT. FIG. 1A shows a dual layer IDT but, according to other embodiments, a single layer IDT can be used.

The top layer of the IDT may be formed from at least one of aluminum, copper, or a combination thereof, and the bottom layer 108a may be formed from—at least one of molybdenum, tungsten, platinum, copper, titanium, chromium, gold, or a combination thereof. Additionally, a material is provided in which the IDT and mass loading strip are encased, 117a, and this may be formed from at least one of silicon dioxide (SiO2), or doped SiO2, such as fluorine doped SiO2 or titanium doped SiO2.

FIG. 1B shows a top plan view and a cross-section view of a second example of an IDT having a mass loading strip. Referring first primarily to the top plan view, in this example the mass loading strip is disposed similarly to FIG. 1A but extends somewhat into the gap region C. The gap is not shown on the left hand side of the lower portion of FIG. 1B, however the mass loading strip 111a on this side also extends into the gap region, as can be seen in the upper portion of FIG. 1B. Of course in FIG. 1B the same components are shown as in FIG. 1A, an IDT comprising an IDT part formed from pair of busbars 103b and 107b, each busbar having extending therefrom a set of electrode fingers, 105a for the first busbar 103b and 109b for the second busbar 107b. The busbars and fingers are disposed on a piezoelectric substrate 101b.

The cross section view depicts the second busbar 107b shown on the right and the first busbar 103b and a first electrode finger 105b shown on the left, atop the piezoelectric substrate 101b. the mass loading strips 111b are shown above and slightly separated from the IDT. The right mass loading strip 111b is above the electrode finger 105b but in this embodiment extends into the gap region C by a small amount. Beneath the IDT is a layer 108b as in FIG. 1A and with the same properties. Additionally the IDT is encased, 117b, as in FIG. 1A.

FIG. 2 shows a top plan view and a cross-ection view an IDT according to another embodiment. Components of the IDT of FIG. 2 are the same as in FIGS. 1A and 1B, however the mass loading part has been modified to improve performance. In particular, the mass loading strip 211 is as in FIG. 1A in that the strip extends only inside the active region B of the IDT. In addition to the mass loading strip 211 there are a number of mass loading stubs 213. The mass loading stubs 213 are disposed vertically in line with the electrode fingers 215 and 219 and into the gap regions A and C. The mass loading stubs 213 are located only in the gap region A and C in regions where the corresponding electrode fingers that are vertically aligned with the respective mass loading stubs are unconnected from the closest busbar. This can be seen in FIG. 2 where each mass loading stub 213 is positioned in one of the gap regions A, C, past the end of the corresponding electrode 205 or 209 that is vertically aligned with the respective mass loading stub 213.

FIG. 2 also has the same basic components as FIG. 1A, an IDT comprising an IDT part formed from pair of busbars 203 and 207, each busbar having extending therefrom a set of electrode fingers, 205 for the first busbar 203 and 209 for the second busbar 207. The busbars and fingers are disposed on a piezoelectric substrate 201.

Each mass loading strip 211 and its associated mass loading stubs 213 can be formed from a single piece of material.

A cross section view is also shown where the second busbar 207 is shown on the right and the first busbar 203 and a first electrode finger 205 is shown on the left, atop the piezoelectric substrate 201. the mass loading strips 211 are shown above and slightly separated from the IDT. The right mass loading strip 211 is above the electrode finger 205. However as noted above in this embodiment a mass loading stub 213 is shown as extending into the gap region C. Beneath the IDT is a layer 208 as in FIG. 1A and with the same properties. Additionally the IDT is encased, 217, as in FIG. 1A.

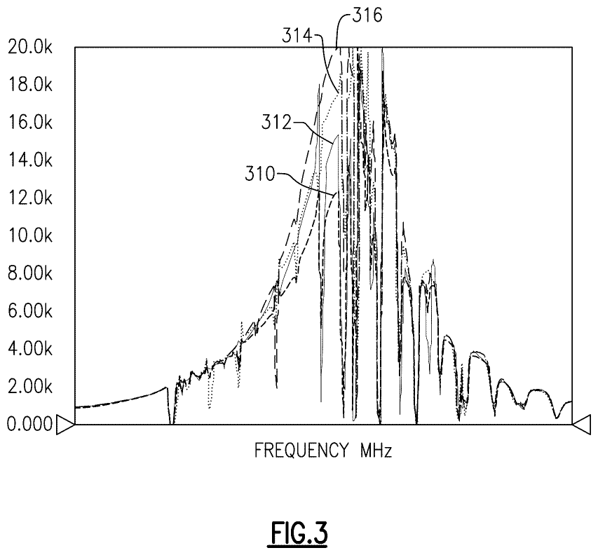

FIG. 3 shows an advantage that the mass loading part can provide. In FIG. 3 the y axis shows a quality metric Q and the higher the curve of the IDT response the lower the spurious wave propagation of the IDT. The X axis is the frequency of the wave. The SAW device comprising the IDT is tuned to pass a certain frequency of wave, and this is reflected in the peak of the plots shown in FIG. 3.

Plot 312 relates to the performance of the IDT shown in FIG. 1A. As can be seen, it reaches approximately 15.0K on the y axis. This is an advantage over an IDT not having a mass loading strip, but it is not the most optimal arrangement according to the present invention. By increasing the width of the mass loading strip 111a to extend into the gap region, such as the mass loading strip 111b, the peak of the output reaches 18.0K on the y axis as can be seen by plot 314 which corresponds to the operation of the IDT shown in FIG. 1B. This is clearly an improvement. However, plot 316 corresponds to the IDT shown in FIG. 2 and according to an aspect of the invention, where it can be seen that the output reaches 20.0K.

Plot 310 relates to the performance of an IDT having a mass loading strip such as 211 in FIG. 2 with mass loading stubs such as 213, however the stubs extend over the connected ends of the electrode fingers. That is, the stubs are displaced such that they are wholly over an IDT electrode and not over a gap within the gap region A or C. It can be seen that this negatively impacts the quality of the IDT. Thus by merely including mass loading stubs, such as 213, an improvement in quality is not guaranteed, and the IDT shown in FIG. 2 is advantageous.

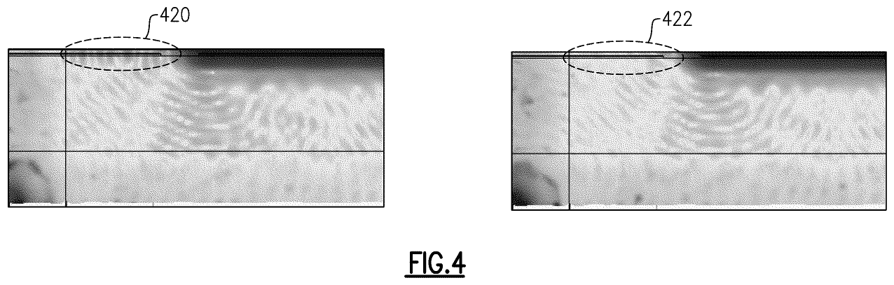

The effect that the mass loading of the IDT shown in FIG. 2 has on the IDT is shown in FIG. 4. FIG. 4 shows the propagation of waves in a cross section of the IDT as a comparison between the IDT such as in FIG. 1B, and the IDT of FIG. 2. The IDT of FIG. 1B is represented on the left hand side and region 420 shows spurious waves propagated outwards from the electrode finger, which is shown as the high density area to the right of the region 420. It can be seen that waves propagate on the surface of the IDT from the electrode finger outwards towards the perimeter of the IDT piezoelectric substrate.

However, the right hand side representation shows, in region 422, that the waves extending outwards from the electrode finger are greatly reduced. This is the effect of the mass loading part comprising the mass loading strips 211 and the mass loading stubs 213 shown in FIG. 2.

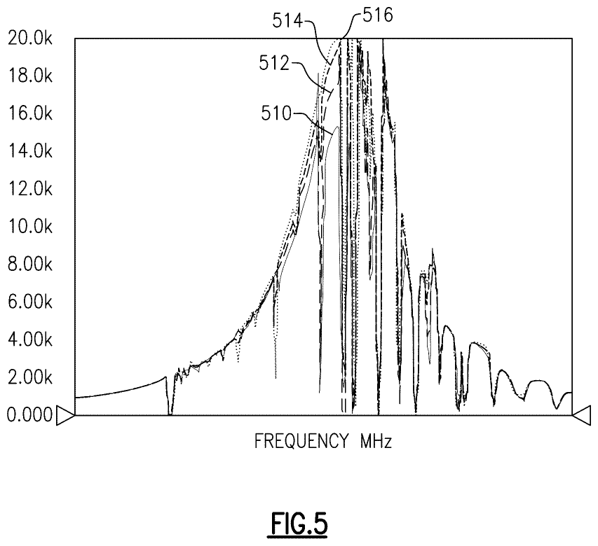

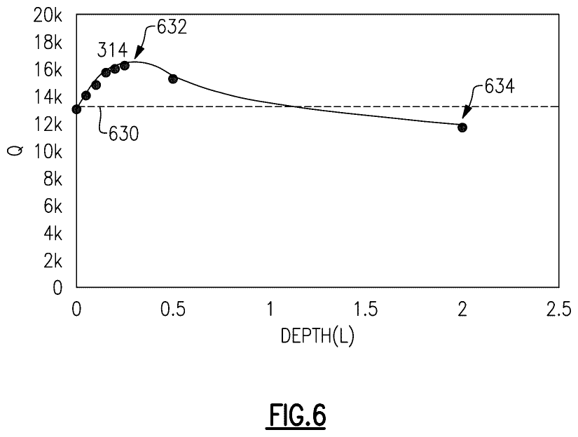

FIGS. 5 and 6 relate to the relative dimensions of the IDT according to the present invention. The IDT dimensions are generally specified in relation to L, the wavelength of the wave propagated by the IDT. This wavelength changes based on characteristics of the IDT such as the distance between the electrode fingers.

In FIG. 5, the improvement of the mass loading parts in relation to their size can be seen. In FIG. 5 the x axis is the frequency of the wave propagated by the IDT and the y axis is the quality of the wave, as in FIG. 3. The various lengths of the mass loading stubs, that is the distance (d) from the mass loading strip to the tip of the stub, are compared. Plot 510 shows the effect where there is no mass loading stubs, that is d=0.00 L. Plot 512 shows the effect where d=0.05 L; plot 514 shows the effect where d=0.10 L; and plot 516 shows the effect where d=0.15 L. The plot in FIG. 5 shows that with an increase in the distance d the quality of the IDT is increased. However, it can also be seen that the improvement between plot 512 and 514 is larger than the improvement from plot 514 to 516. This shows a trend that the improvements are not linear with respect to the changing distance d. This is shown more clearly in FIG. 6

FIG. 6 shows that as d increases the improvements also increase. However this only occurs up to a point, approximately 0.25 L, where the improvement begins to tail off. It can also be seen that all the way from 0 to 1.1 L there is an improvement to the IDT of FIG. 1A, because stubs in this range increase the Q value as shown. In FIG. 6 the axis is the distance d and the quality metric is shown on the y axis. The length of the mass loading stubs is therefore between 0.01 L and 1.1 L, preferably between 0.05 L and 0.5 L, and more preferably 0.25 L.

For reference, a suitable width of the mass loading strip is 0.5 to 1 L, and more preferably 0.6 L. A suitable height of the mass loading strip is between 0.01 and 0.02 L, and more preferably 0.014 L.

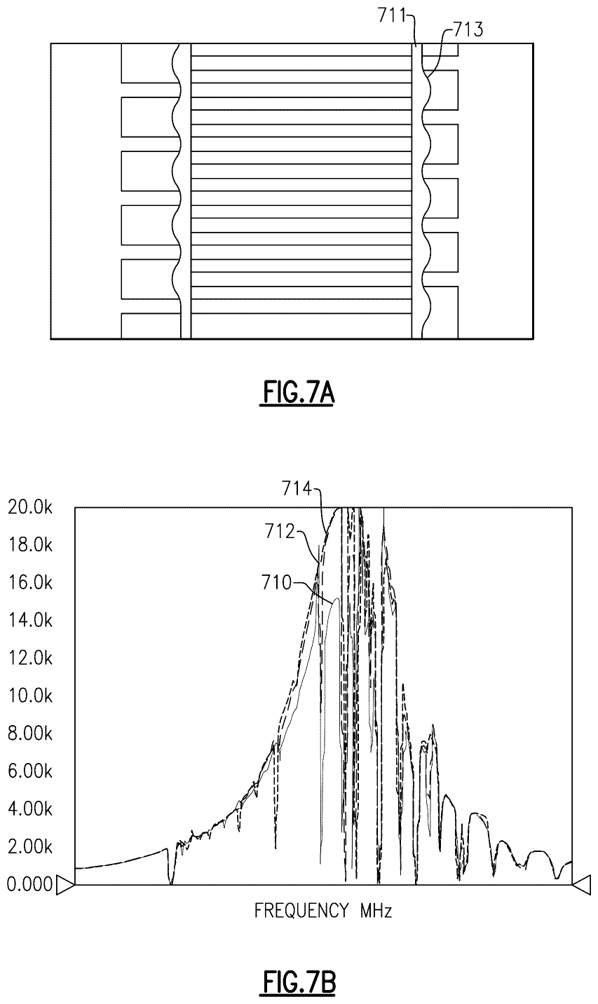

FIG. 7A shows a modified version of the IDT shown in FIG. 2. The mass loading stubs 713 are disposed again adjacent the mass loading strips 711. As with FIG. 2 the mass loading part comprising the strips and stubs are each formed in one piece. The mass loading stubs 713 in this example are disposed such that they form a sinusoidal profile on the mass loading strips 711. The “peaks” of the sinusoidal profile are aligned with the electrode fingers and extend from the tips of the electrode fingers into the gap regions. Essentially the IDT has mass loading stubs 713 which are extended outwardly compared to those of FIG. 2.

FIG. 7B shows the advantage that this has over the IDT from FIG. 1A and the similarity to that of FIG. 2. In FIG. 7B, the y axis shows a quality metric Q and the higher the curve of the IDT response the lower the spurious wave propagation of the IDT. The X axis is the frequency of the wave passed by the IDT.

It can be seen that compared to the IDT of FIG. 1A, shown by plot 710, there is a significant improvement achieved with the mass loading stubs as in FIG. 2, shown by plot 712 and the sinusoidal mass loading of FIG. 7A shown by plot 714.

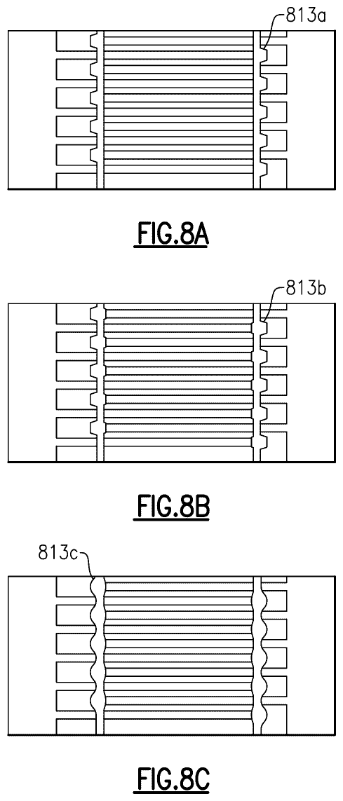

FIGS. 8A, 8B and 8C shown a number of different shapes envisaged for the mass loading stubs of the IDT according to the present invention. For different applications these layouts could have particular benefits. In FIG. 8A the mass loading stubs 813A are wider than the electrode fingers, and so extend past the electrode fingertips in all directions. This can further decrease spurious waves being generated but could also reduce the efficiency of the device where waves are desired to be generated.

FIG. 8B is an extension of this where the stubs 813b extend either side of the mass loading strip to further decrease spurious waves being generated in the gap region. FIG. 8C is a combination of this concept and that of FIG. 7A where the mass loading stubs 813c create a sinusoidal pattern on the mass loading strips and extend either side of the mass loading strips.

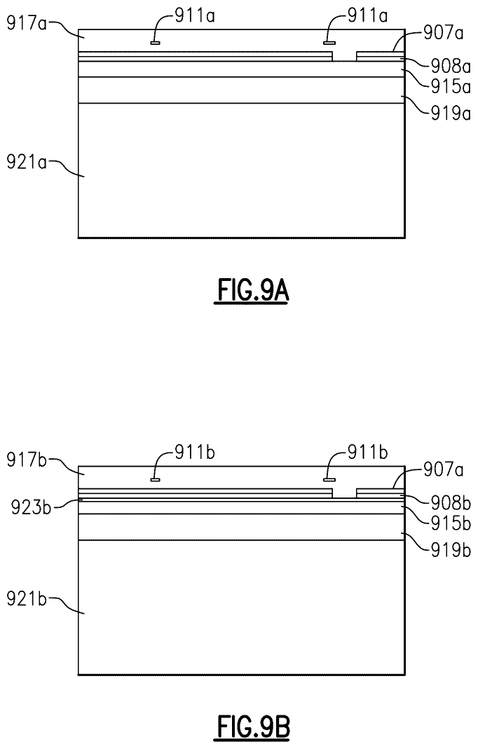

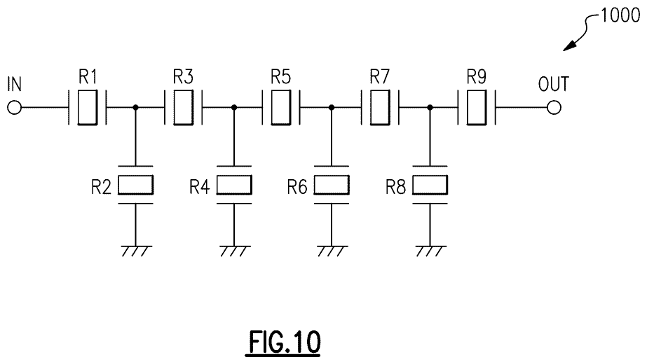

FIG. 9A shows an IDT according to the invention with improved temperature coefficient of frequency properties. In addition to the features of the IDT of FIG. 2, the electrode fingers and busbars 907a, 908a, the piezoelectric substrate 915a and the mass loading part 911a, a silicone base layer is shown, 921a, which provides stability to the IDT and eventual SAW device, and a silicon dioxide later 919a is also shown. The silicon dioxide layer 919a solves a problem where SAW devices become inaccurate when the temperature of the device changes. This can occur when the device is implemented in an electronic circuit containing heat generating components. The temperature chance can change the band-pass of the filter. This means that the filter may tune into a different signal, or that signals need to be spaced far enough apart within the bandwidth of the carrier so that the margin of error of the SAW device does not matter. This problem therefore either decreases the reliability of the filter or wastes bandwidth of a carrier signal. The silicon dioxide TCF layer helps to solve this problem. The silicon dioxide TCF layer 919a (which can also be referred to as a temperature compensation layer) can mitigate temperature drift from the SAW device at both the resonant and anti resonant frequencies.

The TCF layer 919a can be applied to the substrate by chemical vapor deposition, atomic layer deposition, electron cyclotron resonance sputtering or radio frequency sputtering.

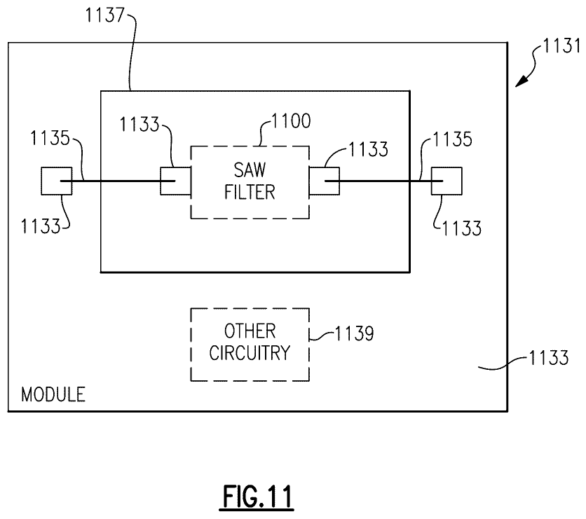

Moreover, examples and embodiments of SAW devices discussed herein can be implemented in a variety of packaged modules. Some example packaged modules will now be discussed in which any suitable principles and advantages of the SAW resonators discussed herein can be implemented. FIGS. 11, 12 and 13 are schematic block diagrams of illustrative packaged modules and devices according to certain embodiments.

FIG. 9B shows an IDT with an added layer 923b providing improved resistance.

SAW devices, such as incorporating the IDT of FIG. 2 FIG. 7A, 8A to 8C and 9A and 9B, can be used in SAW radio frequency (RF) filters.

FIG. 10 shows an example of a filter 1300 in which multiple SAW filters as disclosed herein may be combined. FIG. 10 shows an RF ladder filter 1000 including a plurality of series Lamb wave filters R1, R3, R5, R7, and R9, and a plurality of parallel (or shunt) Lamb wave filters R2, R4, R6, and R8. As shown, the plurality of series Lamb wave filters R1, R3, R5, R7, and R9 are connected in series between the input and the output of the RF ladder filter, and the plurality of parallel Lamb wave filters R2, R4, R6, and R8 are respectively connected between series Lamb wave filters and ground in a shunt configuration. Other filter structures and other circuit structures known in the art that may include Lamb wave filters, for example, duplexers, switchers, delay lines, fractional differentiators, modulators, and etc., may also be formed including examples of Lamb wave filters disclosed herein.

In turn, a SAW RF filter using one or more surface acoustic wave elements as described above may be incorporated into and packaged as a module that may ultimately be used in an electronic device, such as a wireless communications device, for example. FIG. 11 is a block diagram illustrating one example of a module 1131 including a SAW device 1100. The SAW device 1100 may be implemented on one or more die(s) 1137 including one or more connection pads 1133. For example, the SAW device 1100 may include a connection pad 1133 that corresponds to an input contact for the SAW filter and another connection pad 1133 that corresponds to an output contact for the SAW filter. The packaged module 1131 includes a packaging substrate 1132 that is configured to receive a plurality of components, including the die 1137. A plurality of connection pads 1134 can be disposed on the packaging substrate 1132, and the various connection pads 1133 of the SAW filter die 1137 can be connected to the connection pads 1134 on the packaging substrate 1132 via electrical connectors 1135, which can be solder bumps or wirebonds, for example, to allow for passing of various signals to and from the SAW device 1100. The module 1131 may optionally further include other circuitry die 1139, for example, one or more additional filter(s), amplifiers, pre-filters, modulators, demodulators, down converters, and the like, as would be known to one of skill in the art of semiconductor fabrication in view of the disclosure herein. In some embodiments, the module 1131 can also include one or more packaging structures to, for example, provide protection and facilitate easier handling of the module 1131. Such a packaging structure can include an overmold formed over the packaging substrate 1132 and dimensioned to substantially encapsulate the various circuits and components thereon.

Various examples and embodiments of the SAW device 1100 can be used in a wide variety of electronic devices. For example, the SAW device 1100 can be used in an antenna duplexer or diplexer, which itself can be incorporated into a variety of electronic devices, such as RF front-end modules and communication devices.

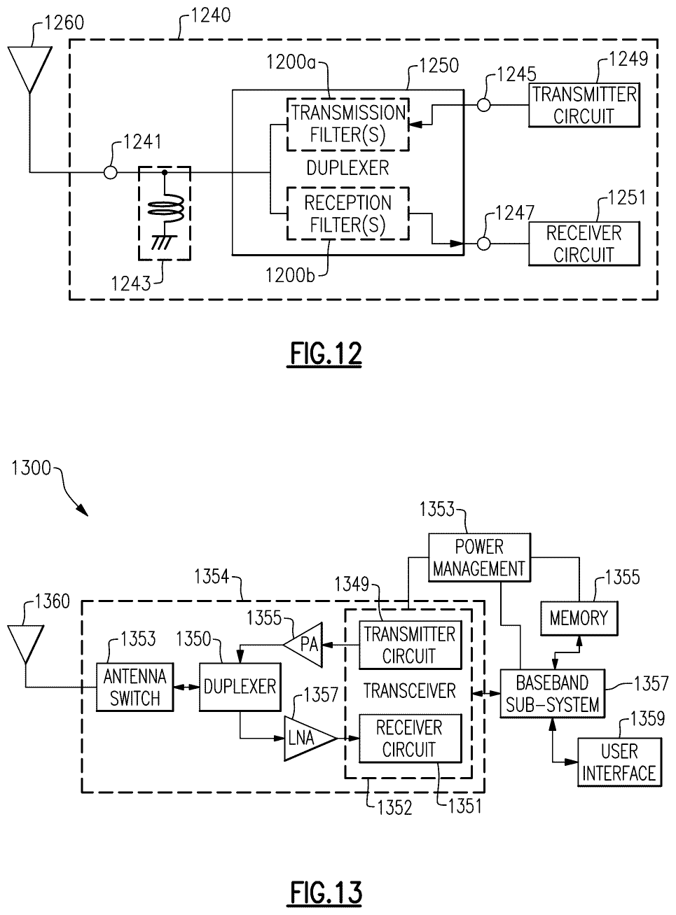

Referring to FIG. 12, there is illustrated a block diagram of one example of a front-end module 1240, which may be used in an electronic device such as a wireless communications device (e.g., a mobile phone) for example. The front-end module 1240 includes an antenna duplexer 1250 having a common node 1241, an input node 1245, and an output node 1247. An antenna 1260 is connected to the common node 1241.

The antenna duplexer 1250 may include one or more transmission filters 1200a connected between the input node 1245 and the common node 1241, and one or more reception filters 1200b connected between the common node 1241 and the output node 1247. The passband(s) of the transmission filter(s) are different from the passband(s) of the reception filters. Examples of the SAW device 1200 can be used to form the transmission filter(s) 1200a and/or the reception filter(s) 1200b. An inductor or other matching component 1243 may be connected at the common node 1241.

The front-end module 1240 further includes a transmitter circuit 949 connected to the input node 1245 of the duplexer 1250 and a receiver circuit 1251 connected to the output node 1247 of the duplexer 1250. The transmitter circuit 1249 can generate signals for transmission via the antenna 1260, and the receiver circuit 1251 can receive and process signals received via the antenna 1260. In some embodiments, the receiver and transmitter circuits are implemented as separate components, as shown in FIG. 12, however, in other embodiments these components may be integrated into a common transceiver circuit or module. As will be appreciated by those skilled in the art, the front-end module 1240 may include other components that are not illustrated in FIG. 12 including, but not limited to, switches, electromagnetic couplers, amplifiers, processors, and the like.

FIG. 13 is a block diagram of one example of a wireless device 1300 including the antenna duplexer 1350 shown in FIG. 9. The wireless device 1300 can be a cellular phone, smart phone, tablet, modem, communication network or any other portable or non-portable device configured for voice or data communication. The wireless device 1300 can receive and transmit signals from the antenna 1360. The wireless device includes an embodiment of a front-end module 1354 similar to that discussed above with reference to FIG. 12. The front-end module 1354 includes the duplexer 1350, as discussed above. In the example shown in FIG. 10 the front-end module 1354 further includes an antenna switch 1353, which can be configured to switch between different frequency bands or modes, such as transmit and receive modes, for example. In the example illustrated in FIG. 13, the antenna switch 1353 is positioned between the duplexer 1350 and the antenna 1360; however, in other examples the duplexer 1350 can be positioned between the antenna switch 1353 and the antenna 1360. In other examples the antenna switch 1353 and the duplexer 1350 can be integrated into a single component.

The front-end module 1354 includes a transceiver 1352 that is configured to generate signals for transmission or to process received signals. The transceiver 1352 can include the transmitter circuit 1349, which can be connected to the input node of the duplexer 1350, and the receiver circuit 1351, which can be connected to the output node of the duplexer 1350, as shown in the example of FIG. 9.

Signals generated for transmission by the transmitter circuit 1349 are received by a power amplifier (PA) module 1355, which amplifies the generated signals from the transceiver 1352. The power amplifier module 1355 can include one or more power amplifiers. The power amplifier module 1355 can be used to amplify a wide variety of RF or other frequency-band transmission signals. For example, the power amplifier module 1355 can receive an enable signal that can be used to pulse the output of the power amplifier to aid in transmitting a wireless local area network (WLAN) signal or any other suitable pulsed signal. The power amplifier module 1355 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 1055 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 13, the front-end module 1354 may further include a low noise amplifier (LNA) module 1357, which amplifies received signals from the antenna 1360 and provides the amplified signals to the receiver circuit 1351 of the transceiver 1330.

The wireless device 1000 of FIG. 13 further includes a power management sub-system 1053 that is connected to the transceiver 1352 and manages the power for the operation of the wireless device 1300. The power management system 1353 can also control the operation of a baseband sub-system 1357 and various other components of the wireless device 1300. The power management system 1353 can include, or can be connected to, a battery (not shown) that supplies power for the various components of the wireless device 1300. The power management system 1320 can further include one or more processors or controllers that can control the transmission of signals, for example. In one embodiment, the baseband sub-system 1357 is connected to a user interface 1359 to facilitate various input and output of voice and/or data provided to and received from the user. The baseband sub-system 1357 can also be connected to memory 1355 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 500 MHz to 3 GHz.

Further examples of the electronic devices that aspects of this disclosure may be implemented include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. An interdigital transducer assembly for a surface acoustic wave device, the interdigital transducer comprising:
a pair of busbars parallel to and spaced from one another and a plurality of interdigitated electrode fingers extending between the pair of busbars, each electrode finger beginning its length at one busbar of the pair of busbars and having an electrode tip that extends towards but does not reach the other busbar, the pair of busbars and the plurality of electrode fingers above a piezoelectric substrate; and
a pair of mass loading strips each parallel and proximate to a corresponding busbar of the pair of busbars, each disposed above a respective set of the electrode tips, and each having a plurality of mass loading stubs arranged along the length of the mass loading strip, each mass loading stub aligned with a corresponding electrode tip of the respective set of electrode tips and extending from the respective mass loading strip, past an end of the corresponding electrode tip, towards the corresponding busbar.

2. The interdigital transducer assembly of claim 1 wherein the plurality of interdigitated electrodes form an active region where the plurality of interdigitated electrode fingers interleave.

3. The interdigital transducer assembly of claim 1 wherein a gap region is formed between each busbar of the pair of busbars and a set of the electrode tips that extend towards that busbar.

4. The interdigital transducer assembly of claim 3 wherein the mass loading strips are configured to reduce an amplitude of waves generated in the gap region.

5. The interdigital transducer assembly of claim 3 wherein the mass loading stubs extend into the gap region.

6. The interdigital transducer assembly of claim 1 wherein the mass loading strips and the mass loading stubs are formed from at least one of molybdenum, tungsten, platinum, titanium, copper, and tantalum pentoxide.

7. The interdigital transducer assembly of claim 1 wherein the mass loading strips have a width of between 0.5 and 1 wavelength of a wave configured to be propagated by the interdigital transducer.

8. The interdigital transducer assembly of claim 1 wherein the mass loading strips have a width of 0.6 of a wavelength of a wave configured to be propagated by the interdigital transducer.

9. The interdigital transducer assembly of claim 1 wherein the mass loading stubs have a length of between 0.01 and 1.1 wavelengths of a wave configured to be propagated by the interdigital transducer.

10. The interdigital transducer assembly of claim 1 wherein the mass loading stubs have a length of between 0.05 and 0.5 wavelengths of a wave configured to be propagated by the interdigital transducer.

11. The interdigital transducer assembly of claim 1 wherein the mass loading stubs have a length of 0.25 of a wave configured to be propagated by the interdigital transducer.

12. The interdigital transducer assembly of claim 1 wherein the interdigital transducer is configured to generate acoustic waves on the piezoelectric substrate.

13. The interdigital transducer assembly of claim 1 wherein the pair of busbars and the electrode fingers include aluminum.

14. The interdigital transducer assembly of claim 1 wherein the pair of busbars the electrode fingers are formed from a first layer and a second layer.

15. The interdigital transducer assembly of claim 14 wherein the first layer is made from aluminum.

16. The interdigital transducer assembly of claim 14 wherein the second layer is made from any of one of tungsten, copper, gold, silver, platinum, ruthenium, molybdenum.

17. The interdigital transducer assembly of claim 1 further comprising a silicon base layer disposed beneath the piezoelectric substrate.

18. A surface acoustic wave device comprising:
a first interdigital transducer including a pair of spaced apart parallel busbars and a plurality of interdigitated electrode fingers extending therebetween, each electrode finger beginning its length at one busbar of the pair and having an electrode tip that extends towards but does not reach the other busbar, the pair of busbars and the plurality of electrode fingers above a piezoelectric substrate, the first interdigital transducer further including a pair of mass loading strips each parallel and proximate to a corresponding busbar of the pair of busbars, each disposed above a respective set of the electrode tips, and each having a plurality of mass loading stubs arranged along the length of the mass loading strip, each mass loading stub aligned with a corresponding electrode tip of the respective set of electrode tips and extending from the respective mass loading strip, past an end of the corresponding electrode tip, towards the corresponding busbar;
a second interdigital transducer; and
a piezoelectric substrate extending beneath and between the first interdigital transducer and the second interdigital transducer.

19. The surface acoustic wave device of claim 18 wherein the first interdigital transducer is configured to generate an acoustic wave in the piezoelectric substrate, and where in the second interdigital transducer is configured to receive the acoustic wave from the piezoelectric substrate.

20. The surface acoustic wave device of claim 18 wherein the second interdigital transducer has the same structure as the first interdigital transducer.
